(19) United States
(12) Patent Application Publication
(10) Pub. No.: US 2003/0025154 A1
(43) Pub. Date: Feb. 6, 2003

(54) LDMOS high voltage structure compatible with VLSI CMOS processes

(76) Inventor: Sheldon D. Haynie, Amherst, NH (US)

Correspondence Address: TEXAS INSTRUMENTS INCORPORATED, P O BOX 655474, M/S 3999, DALLAS, TX, 75265

(21) Appl. No.: 09/921,148

(22) Filed: Aug. 2, 2001

(51) Int. Cl. H01L 29/76

(52) U.S. Cl. 257/335

(57) ABSTRACT

A semiconductor device includes a gate to control the semiconductor device, a drain coupled to the gate, a source to form a current path with the drain, which is formed in a well of a first type of material, a field oxide coupled to the gate, and a channel stop formed under the field oxide and formed of a second type of material.

### FIELD OF THE INVENTION

The present invention relates to a semiconductor device and technique for forming the semiconductor device and particular to a lateral double diffused metal oxide semiconductor device.

### BACKGROUND OF THE INVENTION

Lateral double diffused metal oxide semiconductor transistors (LDMOS) are well known devices which form an integral part of modern day display panels, telecommunication systems, motor controllers, switch lock power supplies, inverters, and alike, when functioning as high voltage drivers. The high voltage characteristics associated with these applications require that the LDMOS devices have the capacity to withstand supply voltages in excess of large voltages sometimes as high as 450 volts without exhibiting breakdown. Furthermore, a desire for LDMOS devices is to have a low on resistance to reduce the power consumption dissipated in the form of heat and to increase current handling capabilities without lowering the breakdown voltage characteristics thereof.

Additionally, the high power applications use lateral double diffused MOS transistors because, of power on resistance R_{DS} (on) faster switching speed and lower gate drive power dissipation then their bipolar counter part. The size and performance of all power IC devices (including LDMOS devices) depends critically ON specific RDS (ON) and particular breakdown voltage of the output devices. Since the field oxide thickness is usually limited by technological constraints, higher breakdown voltages typically require more lightly doped layers. However, since the device on resistance R_{DS} (on) is proportional to the epitaxial layer resistively, higher breakdown voltages must generally be traded off for limited drive current capability. That is, the breakdown voltage of the LDMOS transistors is optimized by adjusting the drift region epitaxial thickness but with increased resistively due to more lightly doped layers. This optimization can also result from reduced surface field (RESURF) techniques. However, the small drift region thickness required to obtain the optimum breakdown voltage often results in objectional increase in the minimum ON resistance, R_{DS} (ON) of RESURF devices.

Additionally, lateral double diffused MOS devices are quickly replacing bipolar devices as the power devices in intelligent power integrated circuits due to their performance advantage. The proliferation of increasingly diversified applications for power-integrated circuits have lead to a desire for components to have a wide range of breakdown voltages.

Double diffused MOS transistor devices (DMOS) are characterized by a source region, a back gate region which is diffused at the same time. The transistor channel is formed by a difference of the two diffusions rather by a separate implantation. DMOS devices have the advantage of decreasing the length of the channel thereby providing low power dissipation and high-speed capability. DMOS devices may be either lateral or vertical configurations. A DMOS device having a lateral configuration is referred to as a LDMOS and has its source and drain at the surface of the semiconductor wafer, and the current is lateral with respect to the surface.

FIG. 1 illustrates a LDMOS device. In FIG. 1, a p-body 108 is located in n-well 114. Additionally, a back gate 110 is formed by p-body 108. A source is formed in p-body 108 adjacent to the back gate 110 and a gate 106 extends from the source 112 to approximately half way across the field oxide or FOX 104. The drain abuts the field oxide 104.

These high voltage devices typically require deep junctions or special field shaping implants. Thus, the processes that are required to achieve these deep junctions or specially shaped field implants are complex and costly as compared to typical low voltage processes. It is desirable to achieve high voltage capacity without these special processes.

### SUMMARY OF THE INVENTION

The present invention provides a structure that increases the high voltage capability of a LDMOS structure. The present invention achieves a high voltage device while using low voltage processes. The present invention uses a shallow floating channel guard ring of opposite type than the substrate to reduce the maximum electric field and improve voltage rating under the FOX.

### BRIEF DESCRIPTION OF THE DRAWINGS

FIG. 1 illustrates a lateral DMOS device;

FIG. 2 illustrates a lateral DMOS device of the present invention;

FIG. 3 illustrates another lateral DMOS device of the present invention;

FIG. 4 illustrates differing voltage potentials of the present invention;

FIG. 5 illustrates carrier generation rate as it relates to breakdown voltage of the present invention;

FIG. 6 illustrates net doping as illustrated in the present invention;

FIGS. 7(a-e) illustrate a process to make the present invention;

FIGS. 8(a-c) illustrate an alternative process to make the present invention;

FIG. 9 illustrates differing voltage potentials associated with the device of FIG. 1; and

FIGS. 10 illustrates carrier generator rates; and;

FIG. 11 illustrates carrier generator rates associated with the device of FIG. 1.

### DETAILED DESCRIPTION OF THE DRAWINGS

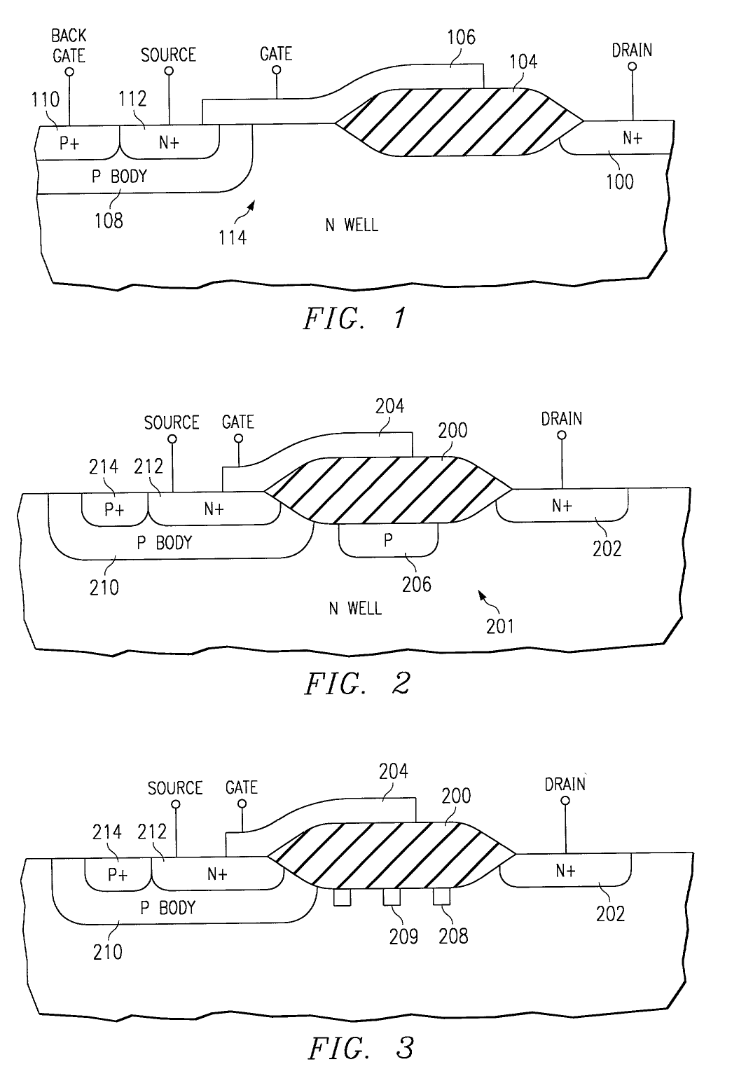

In FIG. 2, a field oxide 200 is formed such that high electric fields can form between the drain 202 and source 212. The high electric fields generate additional carriers that cause the negative resistance which results in a destruction of the device. Additionally, as illustrated in FIG. 2, in the n-well 201 of N material or a first type of material has formed a p-body 210 in which a source of N+ material was formed to create the source and which a back gate 214 is formed of P+ material. Additionally, extending from the source 212, a gate 204 is formed over the n-well 201 to approximately cover one half of the field oxide 200. Adjacent to the field oxide 200 is a N+ region or drain 202. Substantially, under the field oxide 200, is a channel guard ring of P material or a second type of material which is opposite in type to n-well 201, to reduce the maximum electric field and improve voltage ratings with minimal degrading of the ON resistance RDS (on). The choice of n-type material and p-type material could be reversed. This channel guard ring 206 is inside the drift region. The position of the channel guard ring 206 is approximately under the nitride mask that corresponds to the corners of the oxide 200.

FIG. 3 illustrates a series of equal potential rings 208 and 209 under the oxide in the depletion region. Breakdown occurs when the critical voltage of the depletion region is exceeded. These rings 208 and 209 have the function of equalizing potential. More specifically, the potential everywhere on, for example, ring 208 the same potential. These rings 208 and 209 may be spaced at logmetric intervals in the depletion region to improve breakdown voltage. The rings 208 and 209 should be constructed as small as possible. The effect of the rings 208 and 209 is to steer the depletion region into a favorable position. The actual position of the rings 208 and 209 are based on the construction of the drift region and the applied voltage that is intended to be used. The rings 208 and 209 may be positioned by use of a simulator, and the ring is placed for optimum breakdown voltage obtained as a result of simulations from the simulator. Algorithms could be developed for determining the placement of the rings 208 and 209, or it could be done by interactively moving the rings 208 and 209. The present invention with the use of the channel guard ring of opposite type modulates the depletion characteristics of the region. The actual numbers of rings employed by the present invention depends on the voltage that is expected to be applied. For example, under 60 volts no ring should be needed. In the range of 100 volts-200 breakdown volts, either 1, 2, or 3 rings may be progressively needed. As discussed before, the spacing between the rings are not necessarily uniform but should be logmetric. The current flows between the source and drain across the surface of the oxide 200. The floating channel guard ring doping is available in the LBC6 process, for example, boron at 1 EV14. The rings 208 and 209 could be ten to twenty percent of the area under the FOX 200.

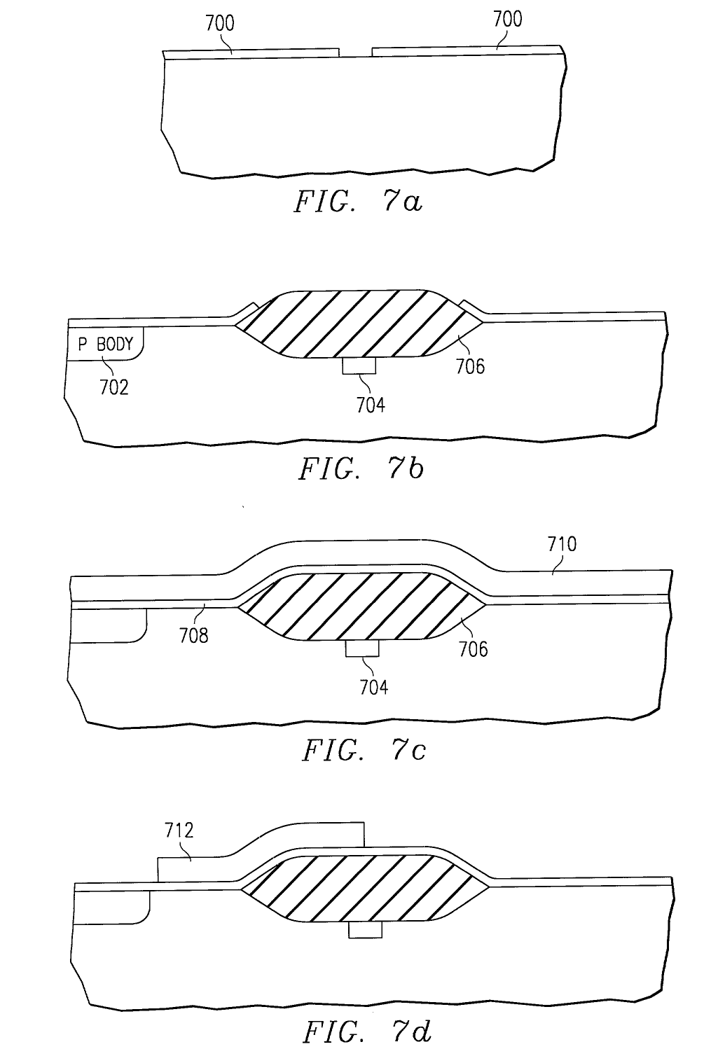

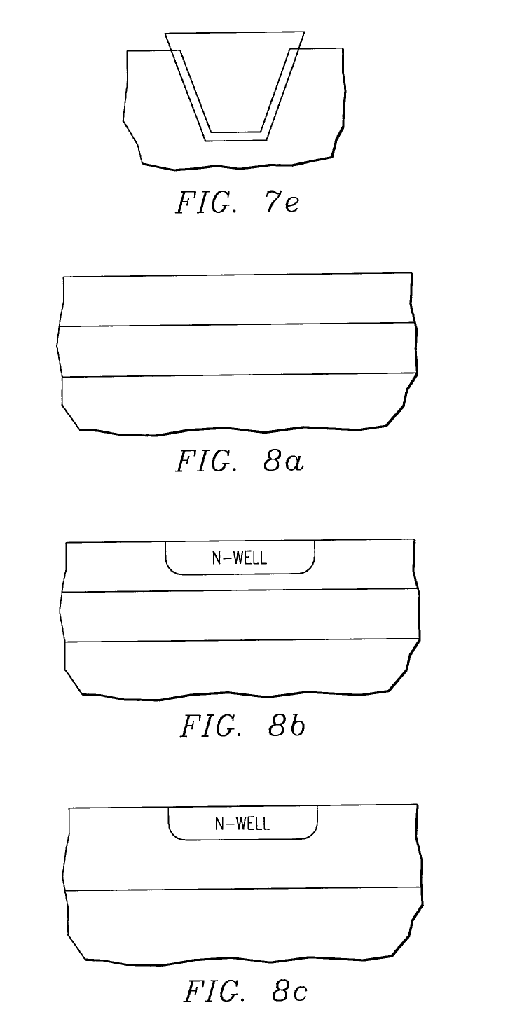

The process that forms the devices discussed above is illustrated in FIG. 7. In FIG. 7A, a mask 700 is placed on the n-type epi material. The mask 700 may be silicon nitride Si3N4, photoresist, or SiO4. Doping is achieved by implanting. Next, the device is subject to an oxidizing ambient for example, O2 or H2 O at 900 degrees to 1200 degrees Centigrade at which point the field oxide 706 is grown and the p-body 702 and the floating channel guard ring 704 are driven.

FIG. 7B shows an alternate method of growing the field oxide in a shallow trench by oxidizing an undoped polysilicon and a silicon nitride and/or thermally grown along the edges of the shallow trench. Next, an implant is used with boron after thermal oxidation.

Turning now to FIG. 7C the device is covered with a gate insulator 708. Next, an additional layer 710 is deposited which may be polysilicon, which is intrinsically doped or a metal overlay device. Next as illustrated in FIG. 7D, the gate 712 is formed by using a pattern and etching.

FIG. 8 illustrates alternatives for forming the substrate. In FIG. 8A, an epi layer is formed over a P layer. FIG. 8B illustrates a p-substrate under a p-epi layer that includes an n-well. FIG. 8C illustrates an n-well with p-substrate.

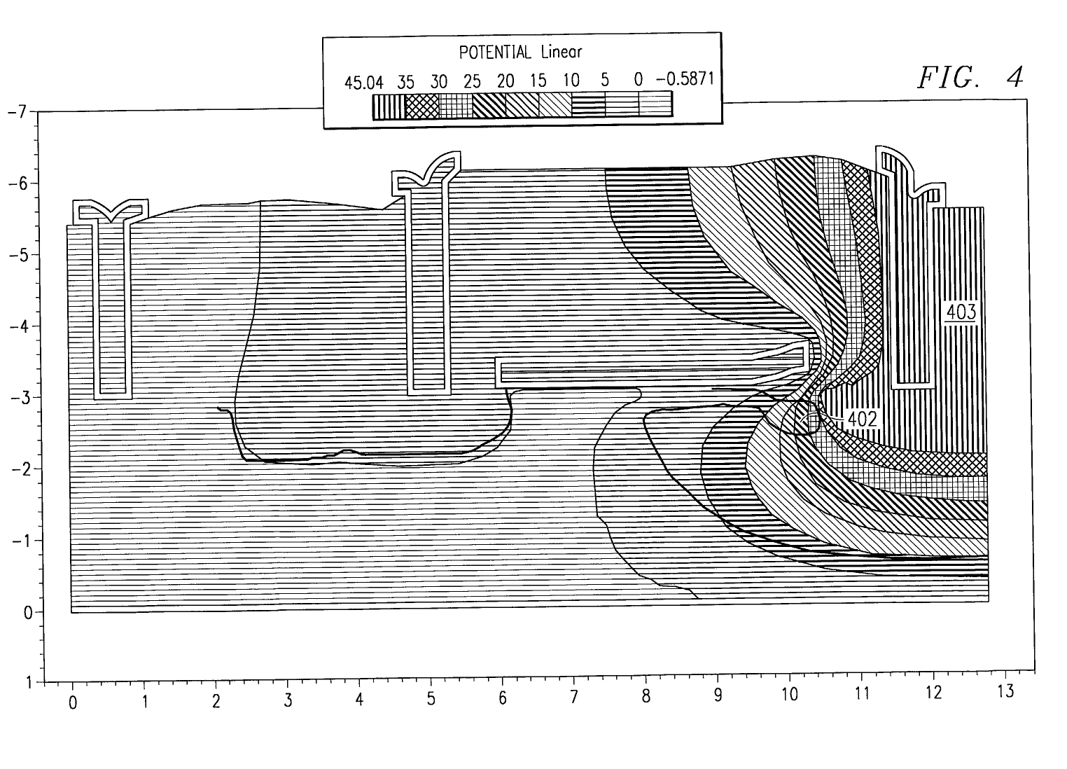

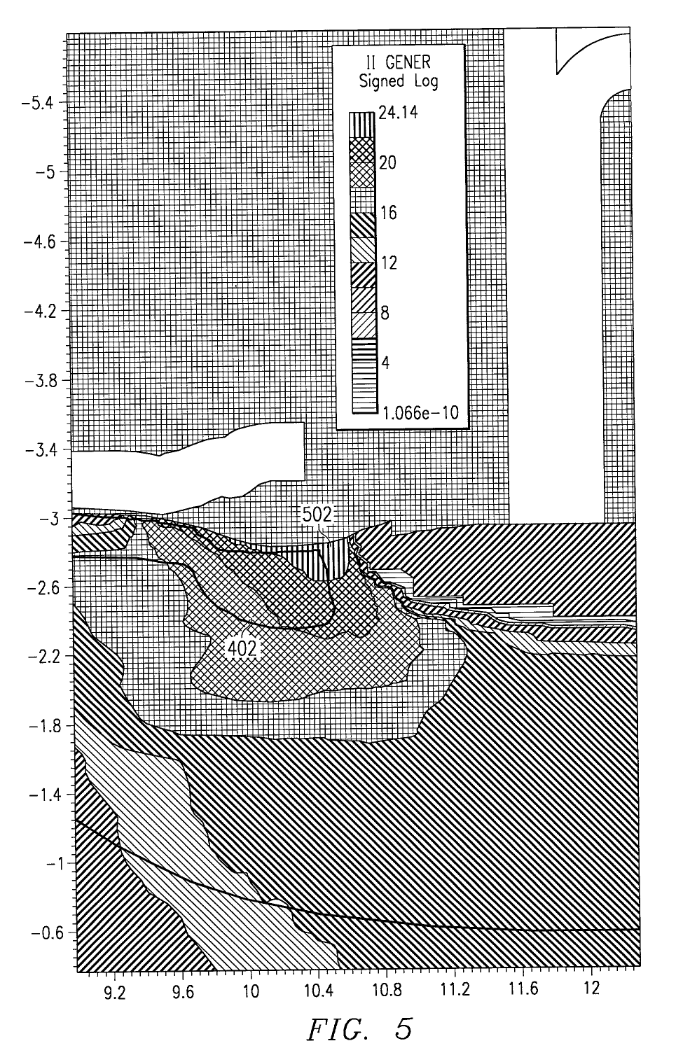

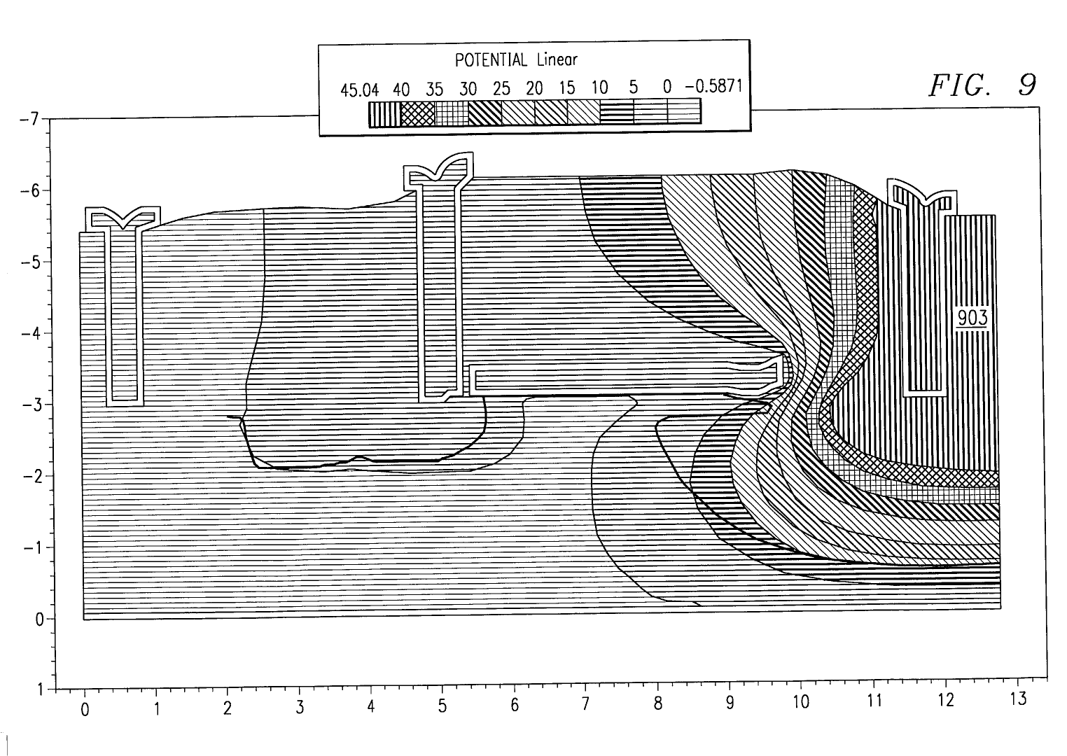

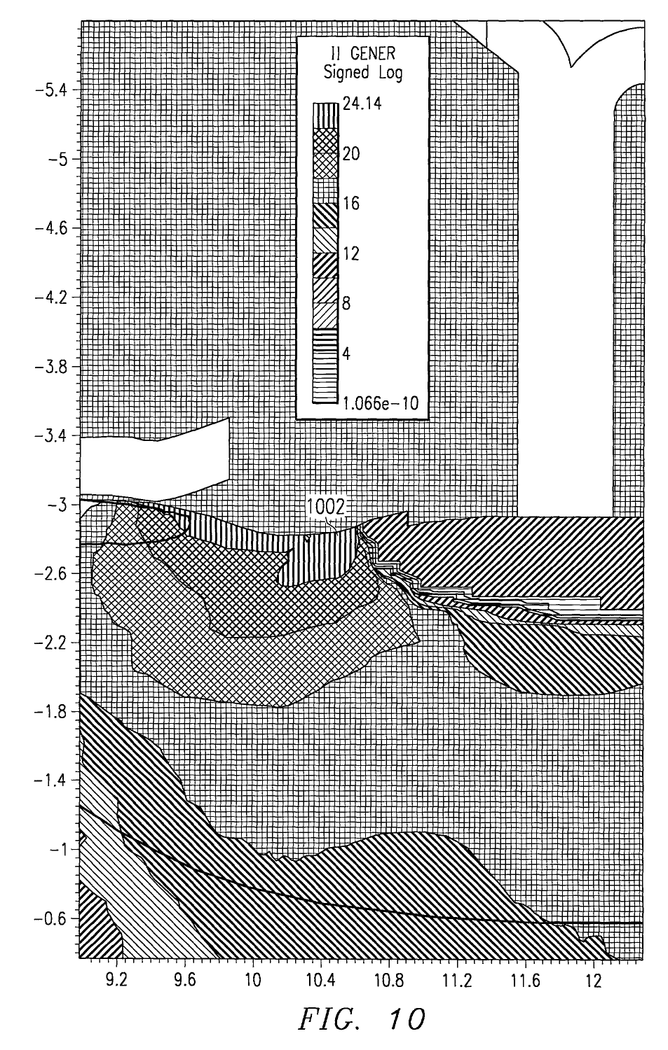

FIG. 4 includes a channel guard ring while FIG. 9 is without a floating channel guard ring. The channel guard ring is illustrated as element 402. The area 403 illustrating the highest voltage potential is significantly less than the corresponding area 903 in FIG. 9 without the floating channel guard ring. Thus, higher breakdown voltage is achieved.

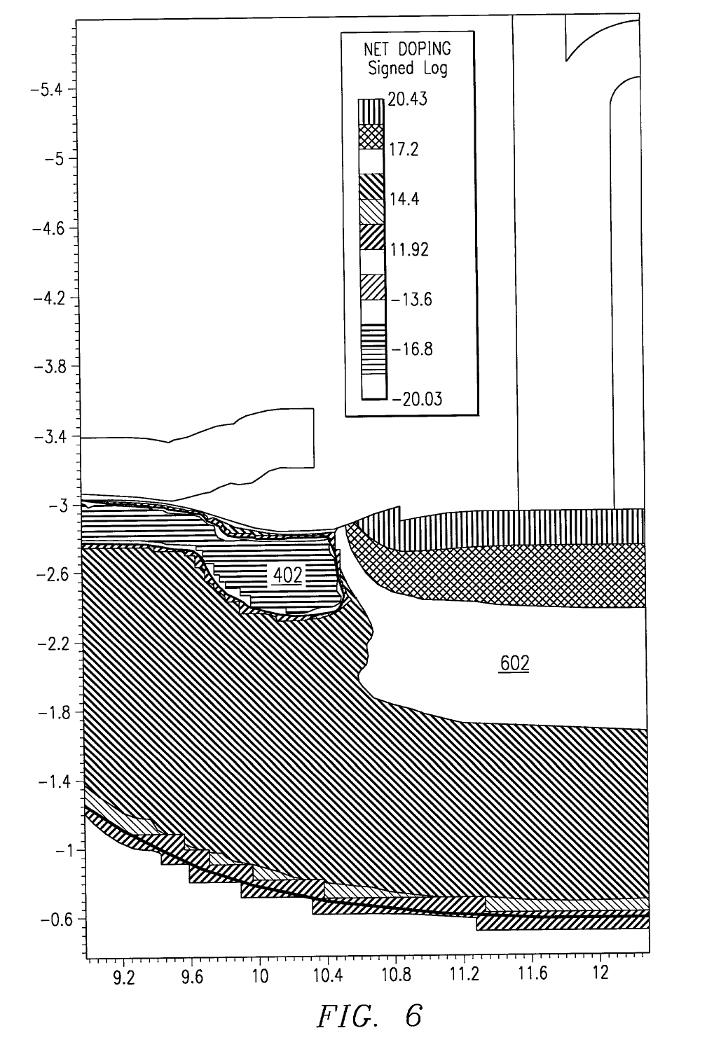

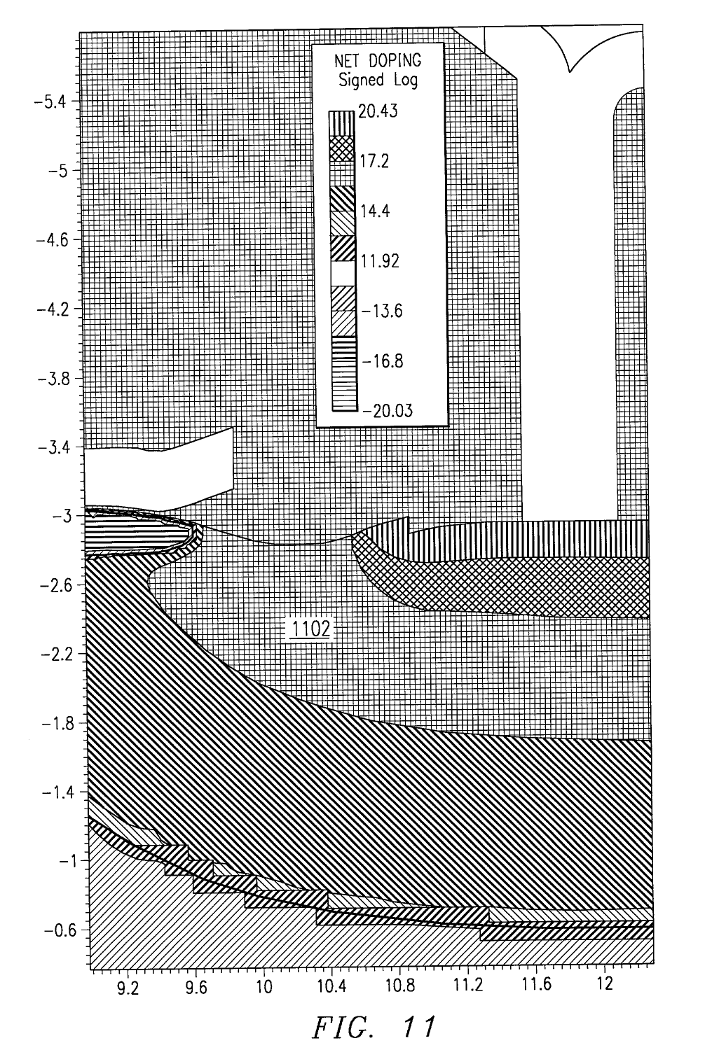

FIG. 5 illustrates an enlarged version of FIG. 4 showing the area around the floating channel guard ring 402 of opposite type. Again the area of highest voltage potential in FIG. 5 is area 502 and this area is significantly smaller than the area 1002 shown in FIG. 10. Again, highlighting the differences of the present invention, and the higher breakdown voltage achievable by the present invention. Again, comparing FIG. 6, which shows the doping levels with the floating channel guard ring 402 of opposite type and FIG. 11 which shows the doping levels corresponding to a device without the special field the channel guard ring 402. These two figures show varies carrier generation rates to indicate the breakdown. It can be seen the carrier generation rate in area 602 is correspondingly smaller then the carrier generation rate in FIG. 11 by corresponding area 1102.

1. A semiconductor device, comprising:
a well of a first type a gate;
a gate to control said semiconductor device;
a drain coupled to said gate formed in said well of the first type;
a source to form a current path with said drain;
a field oxide area coupled to said gate; and
a channel stop under said field oxide area of a second type.

2. A semiconductor device as in claim 1, wherein said channel stop is a p-type channel stop.

3. A semiconductor device as in claim 1, wherein said source is n-type material.

4. A semiconductor device as in claim 1, wherein said drain is n-type material.

5. A semiconductor device as in claim 1, wherein said channel stop includes a first channel stop and a second channel stop, said first channel stop not being directly connected to said second channel stop.

6. A semiconductor device as in claim 5, wherein said first channel stop is a p-type channel stop.

7. A semiconductor device as in claim 6, wherein said second channel stop is a p-type channel stop.

8. A semiconductor device as in claim 5 wherein said first channel stop is a ring.

9. A semiconductor device as in claim 5 wherein said second channel stop is a ring.
